(19) United States
(12) Patent Application Publication
(10) Pub. No.: US 2002/0066923 A1
(43) Pub. Date: Jun. 6, 2002

(54) Non-volatile flash memory cell with short floating gate

(75) Inventors: Fu-Cheng Jong, Tainan City (TW); Kent Kuohua Chang, Taipei City (TW); Chia-Hsing Chen, Hsin-Chu City (TW)

Correspondence Address: LOWE HAUPTMAN GILMAN & BERNER, LLP, Suite 310, 1700 Diagonal Road, Alexandria, VA, 22314, US

(73) Assignee: MACRONIX INTERNATIONAL CO., LTD.

(21) Appl. No.: 09/729,829

(22) Filed: Dec. 6, 2000

(51) Int. Cl. H01L 29/788

(52) U.S. Cl. 257/316; 257/321

(57) ABSTRACT

A non-volatile flash memory cell with a short floating gate comprises: a channel region which is located in a surface of a substrate and between a source and a drain; a control gate which is located over the channel region and simultaneously insulated to the channel region; and a floating gate which is located between the channel region and the control gate, and simultaneously insulated to each other, wherein a width of the floating gate is less than the control gate and the channel region. Besides, the floating gate and the control gate are approximately parallel, and a bottom of the control gate is more far from the substrate than a top of the floating gate. Obviously, the characteristic of the present invention is the channel region can divide to two parts which one is under and another is not under the floating gate. However, even the over erase causes the short of the channel region which is under the floating gate, the channel region which is not under the floating gate still is not conducted. Hence, the present invention can effectively prevent the abnormal operation of the non-volatile flash memory cell.

### BACKGROUND OF THE INVENTION

1. Field of the Invention

The present invention generally relates to a non-volatile flash memory cell, and more particularly relates to a non-volatile flash memory cell which can prevent the abnormal erase by leting a width of a floating gate is shorter than a width of a control gate.

2. Description of the Prior Art

Flash memory have been broadly applied to replicatively access data but not disappear as power breaking down, such as the film of digital camera or the basic input-output system of a mother board, because flash memory has the advantages of electrically erasable and programmable mechanisms. Flash memory can simultaneously proceed the erase and the program mechanisms to all flash memory cells in the whole memory's array. Accordingly, how to advance the performance and reduce the cost of flash memory becomes an important subject.

Referring to FIG. 1A, a common structure of a flash memory cell is a stacked structure which basically comprises a source 11, a drain 12, a floating gate 13, and a control gate 14. The source 11, the drain 12, and the control gate 14 are connected with different voltages to control the programming process, the reading process, and the erasing process of flash memory. The floating gate 13 and the control gate 14 are surrounded by a dielectric layer 15 on a substrate 10.

In respect to an N type flash memory cell (the substrate 10 is an N type substrate), the source is grounded, and the control gate 14 and the drain 12 are put a positive voltage in a programming mechanism. Because there is not using a light doped drain, so partial electrons will diffuse into the floating gate 13 and is trapped in the floating gate 13 the potential barrier of the surrounding dielectric layer 15. However, electrons in the floating gate 13 will effect the threshold voltage of the channel region between the source 11 and the drain 12, and control the conduction of the channel region. Then, electrons in the floating gate 13 can be reputed as data which is read by the conduction of the channel region. In an erasing mechanism, the source 11 is grounded, and the control gate 14 is put a positive voltage which is lower than the drain 12. Electrons in the floating gate 13 will disappear by Fowler-Nordheim tunneling.

Obviously, the performance of flash memory cell will be affected by the under erase (residual electrons in the floating gate 13) or the over erase (further bring positive charges 16 from the floating gate 13), as shown in FIG. 1B. For example, the over erase of flash memory causes not proceeding the accessing data because positive charges 16 in the floating gate 13 will result to charge neutrality or the change of the conduction of the channel region. Furthermore, the flash memory could not access any data if positive charges 16 in the floating gate 13 are so many to automatically conduct the channel region.

Besides, because flash memory array often comprises many flash memory cells in actual applications, such as a bit line of a low-density high-response rate “NOR” structure. Therefore, an abnormal operation of a single flash memory cell often causes the lapse of the whole flash memory array.

If the problem of abnormal erase is solved by a application of a circuit way, it must add a testing circuit in each cell which will complicate the structure of flash memory, reduce the available area of flash memory array, and increase the testing time and cost.

Another way to solve this problem is to use a split gate. Referring to FIG. 1C, in this time, the channel region can divide to two parts which one is only having the control gate 17 thereon and another is both having the control gate 17 and the floating gate 17 thereon. Obviously, as shown in FIG. 1D, positive charges 18 in the floating gate 18 are accrued when the abnormal erase happens. However, there is only the channel region under the floating gate 18 could not control the conduction, and the channel region which is not under the floating gate 18 can still control by the control gate 17. In other word, the problem of the over erase can be effectively prevent and almost use a drain hot carriers injection method, which the efficiency is about 100 times efficiency of the source hot carriers injection method, to inject electrons into the floating gate 18. Certainly, the type and the proceeding way of the split gate can have many varieties, as references to U.S. Pat. Nos. 4,639,893, 5,486,711, and 4,868,629.

Comparing FIG. 1A and FIG. 1C, the structure of flash memory cell with a split gate is more complicated than the structure of the stacked structure of flash memory cell, especially the shapes of the control gate 17 and the control gate 14 are different. Moreover, the flash memory cell with a split gate has a higher cost in complicated processes. Further, in the antecedent of the same function of the floating gate 18 and the floating gate 13, the area of flash memory cell with a split gate is bigger because the length of the control gate 17 is longer than the length of the control gate 14.

As above discussions, conventional structures of all kinds of flash memory cell could not effectively prevent the abnormal erase, or can solve the problem but complicate the process and increase the cost. Hence, it needs to develop a new structure of flash memory cell to effectively enhance programming and erasing.

### SUMMARY OF THE INVENTION

The primary object of the invention is to provide a non-volatile flash memory cell which can effectively prevent the abnormal erase.

Another object of the invention is not only to prevent the abnormal erase but also provides a simple structure of a non-volatile flash memory cell.

A further object of the invention is in an antecedent of not obviously modifying the structure of a stacked flash memory cell to prevent the abnormal erase.

The invention further comprises a object to prevent the abnormal erase in an NOR structure of an N type flash memory.

In order to achieve previous objects of the invention, a non-volatile flash memory cell is provided. The non-volatile flash memory cell comprises: a channel region which is located in a surface of a substrate and between a source and a drain; a control gate which is located over the channel region and simultaneously insulated to the channel region; and a floating gate which is located between the channel region and the control gate, and simultaneously insulated to each other, wherein a width of the floating gate is less than the control gate and the channel region. Besides, the floating gate and the control gate are approximately parallel, and a bottom of the control gate is more far from the substrate than a top of the floating gate.

Obviously, the present invention is a mixture of a stacked flash memory cell and a split gate of flash memory cell. On one hand, the channel region divide to two parts, which one will be affected and another will not be affected by the over erase. On the other hand, the process of the present invention is still simple.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1A is the schematic representation of the structure of a conventional stacked flash memory cell;

FIG. 1B is the schematic representation of the structure of a conventional stacked flash memory cell in the over erase;

FIG. 1C is the schematic representation of the structure of a conventional flash memory cell with a split gate;

FIG. 1D is the schematic representation of the structure of a conventional flash memory cell with a split gate in the over erase;

FIG. 2A is the schematic representation of one structure of a flash memory cell, in accordance with the present invention;

FIG. 2B is the mechanism schematic representation of the structure of a flash memory cell to prevent the abnormal erase, in accordance with the present invention;

FIG. 2C is the schematic representation of another structure of a flash memory cell, in accordance with the present invention;

FIG. 2D is the mechanism schematic representation of another structure of a flash memory cell to prevent the abnormal erase, in accordance with the present invention; and

FIG. 2E is the schematic representation of another structure of a flash memory cell, in accordance with the present invention.

### DESCRIPTION OF THE PREFERRED EMBODIMENT

Aims at main drawbacks of a conventional flash memory cell with a split gate: complicated processes and big chip area. The present invention points out a key point is that the commanding of controlling the conduction of the channel region is to the voltage put on the channel region but not the distance between the gate and the substrate. In the other word, the method to prevent the abnormal erase is to divide the channel region into two parts, which one is under and another is not under the floating gate. The distance between the control gate and the substrate to control the conduction of the channel region which is not under the floating gate is not necessary the same to the distance between the floating gate and the substrate. However, when the voltage to the control gate is only big enough, the distance between the control gate and the substrate to control the conduction of the channel region which is not under the floating gate can be bigger than the distance between the floating gate and the substrate. Certainly, the distance between the control gate and the substrate is bigger, the needed voltage to control the conduction of the channel region is higher.

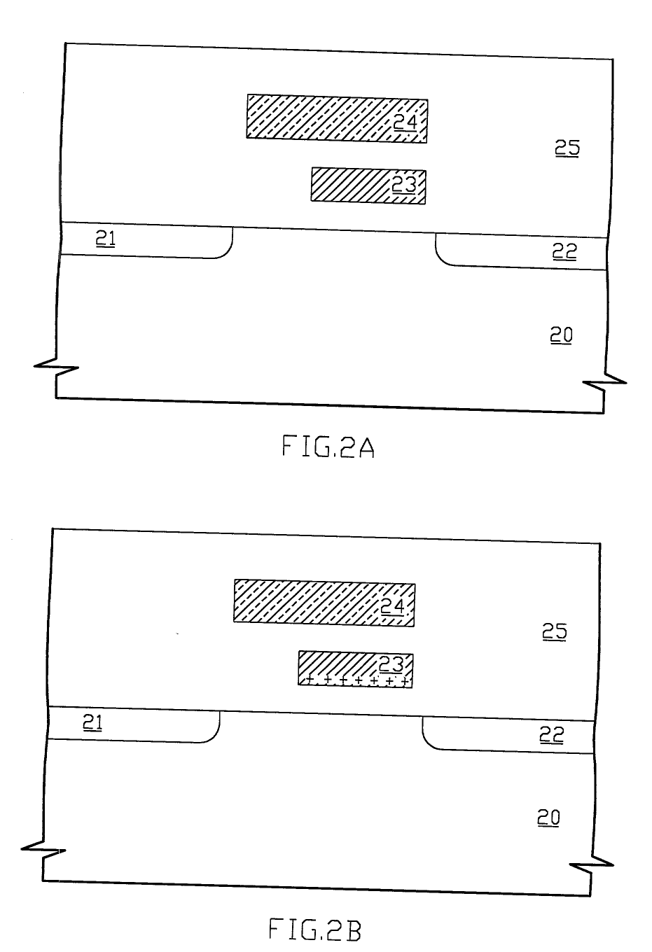

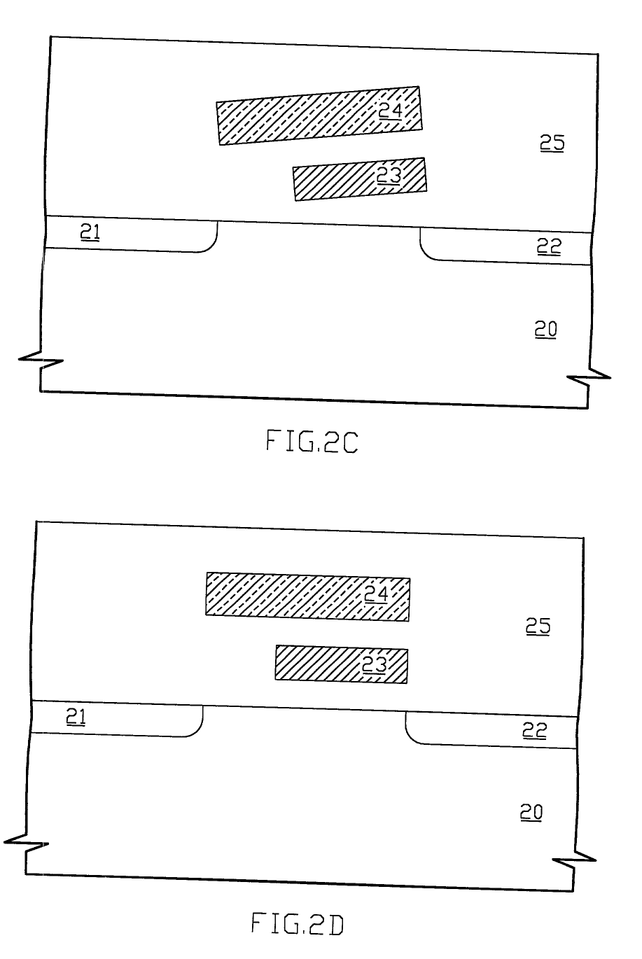

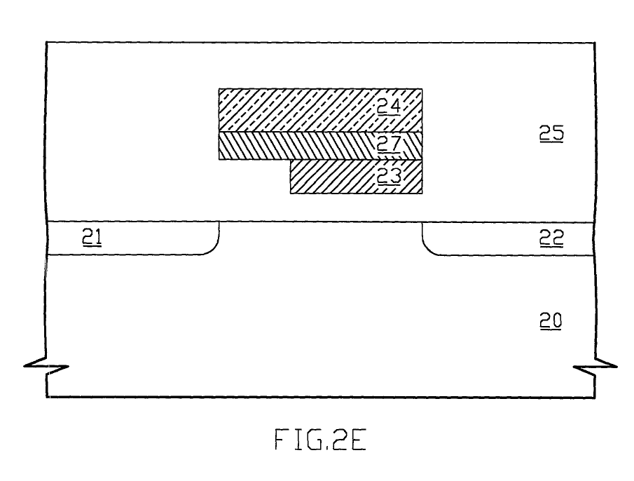

According to the above idea, the present invention provides a non-volatile flash memory cell, as shown in FIG. 2A. The non-volatile flash memory cell comprises a source 21, a drain 22, a floating gate 23, and a control gate 24. The floating gate 23 and the control gate 24 are located in a dielectric layer 25, whereby a substrate 20, the floating gate 23, and the control gate 24 are insulated to each other.

Herein, the source 21 and the drain 22 are located in a surface of the substrate 20, such as a P type substrate, and a channel region is in a surface of the substrate 20 and between the source 21 and the drain 22. The control gate 24 is located over the channel region and insulated with the channel region. The floating gate 23 is located between the channel region and the control gate 24, and simultaneously insulated to each other. Herein, a width of the floating gate 23 is not only smaller than a width of the control gate 24 but also smaller than a width of the channel region, and the floating gate 23 and the control gate 24 are approximately parallel to each other.

Obviously, because the floating gate 23 is shorter than the control gate 24, the threshold voltage of the part under the floating gate 23 is lower than the threshold voltage of the part under the control gate 24 in the programming process. Then, the depletion region near the drain 22 will extended to the direction of the source 21 and electrons (a few carriers of the P type substrate) will be injected into the floating gate 23 by a source hot carriers injection method. According as the increasing amount of electrons, the input point will near to the drain 22. In this time, the channel region can be divide to two parts which one is directly under the floating gate 23 and another is not directly under the floating gate 23. As a conventional flash memory cell with a split gate, controlling the control gate 24 can be used to adjust the conduction or not conduction of the part which is not directly under the floating gate 23, as shown in FIG. 2B. Then, the present invention can prevent the abnormal erase (as positive charges 26 shown in the floating gate 23), which is the abnormal operation of the part, which is the channel region directly under the floating gate 23, to make the whole flash memory cell abate. Last, when erasing the cell is needed, it only need put a positive voltage to the drain 22 and a negative voltage to the control gate 24, and then electrons in the floating gate 23 will be pushed to the drain 22 by Fowler-Nordheim tunneling.

Obviously, the present invention can effectively prevent the abnormal eras which make the flash memory cell abate. Hence, the present invention can prevent the abnormal erase of a NOR structure of flash memory. However, because the present invention only need to modify the structure of flash memory cell without additional testing circuits to test the flash memory array, the present invention can economize chips area, testing time, and reducing the cost.

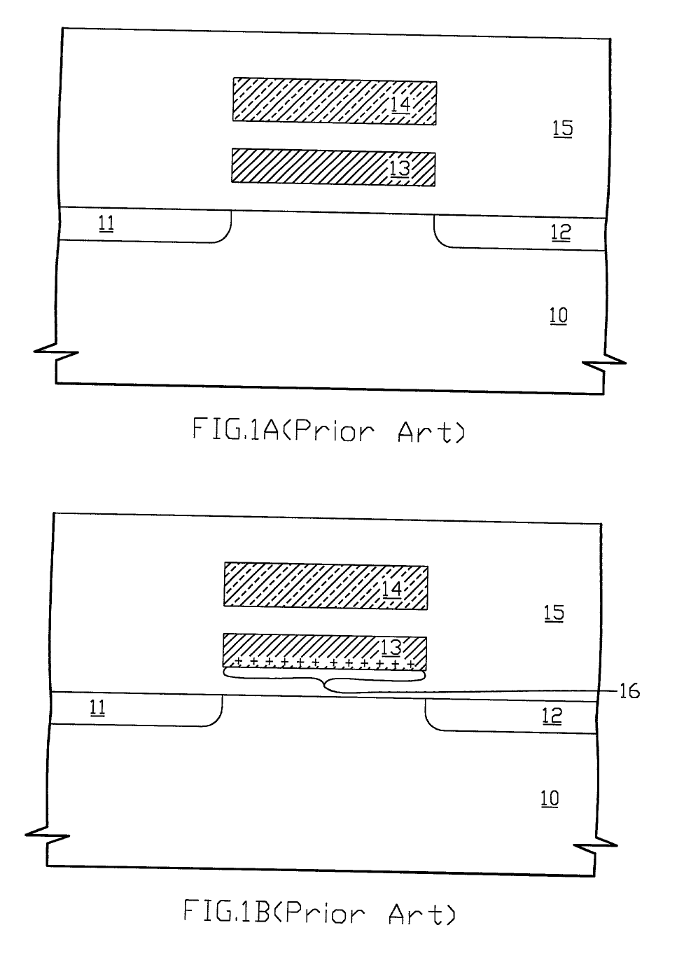

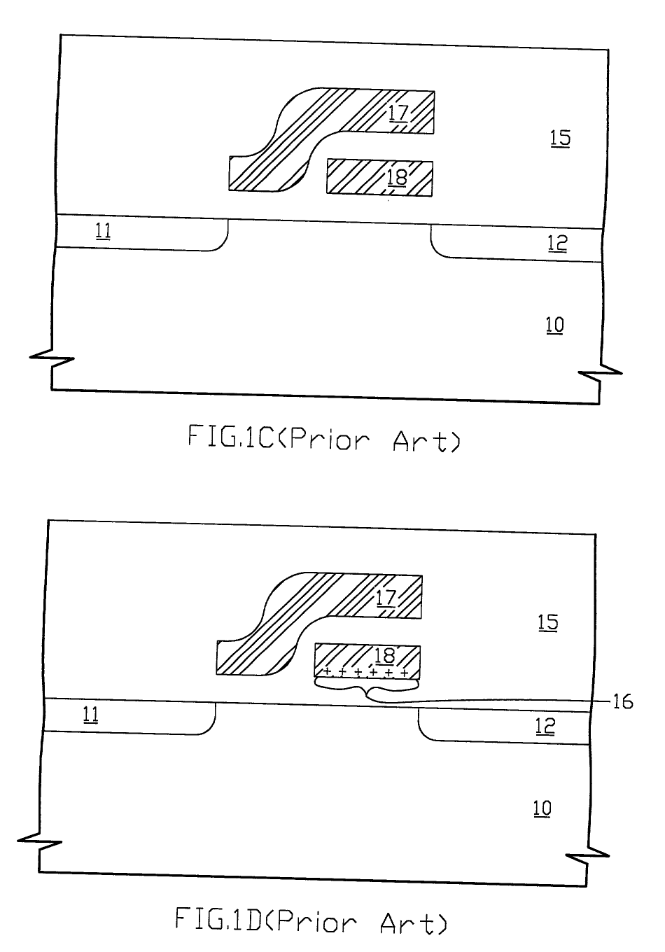

Comparing FIG. 2A, FIG. 1A, and FIG. 1C, the present invention is basically a stacked flash memory cell. The control gate 24 and the floating gate 23 are approximately parallel to each other, and a bottom of the control gate 24 is more far from the substrate 20 than a top of the floating gate 23. The shapes of the control gate 24 and the floating gate 23 are simple and can be formed by using a depositing process and an lithography process. Furthermore, the formation of the control gate 24 and the floating gate 23 is simple and do not need any processes to form the bow control gate 17, as shown in FIG. 1C.

Although, the floating gate 13 and the substrate 20 are parallel in FIG. 2A, but the present invention is not limited by it. Referring to FIG. 2C, the control gate 24 and the floating gate 23 can be atilt to each other to enhance the control gate 24 to control the channel region which is not located under the floating gate 23.

Certainly, one side of the floating gate 23 can be aligned to an edge one side of the drain 22 which is near said source 21, and another side can be aligned to an edge of one side of the source 21 which is near the drain 22 to make sure the normal operation and to raise the efficiency of the erasing process, as shown in FIG. 2D.

Last, as shown in FIG. 2E, the control gate 24 and the floating gate 23 are separated with a composite dielectric layer 27 to increase the dielectric constant and the storing time of electrons in the floating gate 23. Herein, the composite dielectric layer 27 is formed by stacking three dielectric layers, which the middle layer is selected from the group: silicon nitride or silicon nitride oxide, and two surface layers is made of oxide.

Of course, it is to be understood that the invention need not be limited to these disclosed embodiments. Various modification and similar changes are still possible within the spirit of this invention. In this way, the scope of this invention should be defined by the appended claims.

What is claimed is:

1. A non-volatile flash memory cell, said memory cell comprising:
a channel region which is located in a surface of a substrate and between a source and a drain, wherein said source and said drain are in said surface of said substrate;
a control gate which is located over said channel region, wherein said control gate and said channel region are insulated to each other; and
a floating gate which is located between said channel region and said control gate, wherein said floating gate, said control gate, and said channel region are simultaneously insulated to each other, and a width of said floating gate is less than a width of said control gate and a width of said channel region, wherein said floating gate and said control gate are approximately parallel.

2. The memory according to claim 1, wherein said substrate is a P typed substrate.

3. The memory according to claim 1, wherein said floating gate and said substrate are approximately parallel.

4. The memory according to claim 1, wherein one side of said floating gate is aligned to an edge of said source which is near said drain.

5. The memory according to claim 1, wherein one side of said floating gate is aligned to an edge of said drain which is near said source.

6. The memory according to claim 1, wherein said control gate and said floating gate are insulated with a composite dielectric layer.

7. The memory according to claim 6, wherein said composite dielectric layer is formed by stacked three dielectric layers.

8. The memory according to claim 7, wherein a middle layer of said three dielectric layers is selected from the group consisting of silicon nitride layer or silicon nitride oxide layer.

9. The memory according to claim 7, wherein two surface layers of said three dielectric layers are made of oxide.

10. The memory according to claim 1, wherein said floating gate and said substrate are insulated with a dielectric layer.

11. The memory according to claim 1, wherein said floating gate has been injected a plurality of electrons into by using a drain hot carrier injection method.

12. A non-volatile flash memory cell, said memory cell comprising:
a channel region which is located in a surface of a substrate and between a source and a drain, wherein said source and said drain are in said surface of said substrate;
a floating gate which is located over said channel region, wherein said floating gate and said channel region are insulated to each other; and
a control gate which is located under said channel region and said floating gate, wherein said control gate, said floating gate, and said channel region are simultaneously insulated to each other, and a width of said control gate being greater than a width of said floating gate, wherein a bottom of said control gate is more far from said substrate than a top of said floating gate, and one side of said control gate is aligned to an edge of said drain which is near said source.

13. The memory according to claim 12, wherein said substrate is a P type substrate.

14. The memory according to claim 12, wherein said control gate is approximately parallel to said substrate.

15. The memory according to claim 12, wherein said control gate is approximately parallel to said substrate.

16. The memory according to claim 12, wherein said control gate and said floating gate are insulated with a composite dielectric layer.

17. The memory according to claim 16, wherein said composite dielectric layer is formed by stacked three dielectric layers.

18. The memory according to claim 17, wherein a middle layer of said three dielectric layers is selected from the group consisting of silicon nitride layer or silicon nitride oxide layer.

19. The memory according to claim 17, wherein two surface layers of said three dielectric layers are made of oxide.

20. The memory according to claim 12, wherein said floating gate and said substrate are insulated with a silicon oxide layer.
